(19) United States
(12) Patent Application Publication
(10) Pub. No.: US 2017/0117164 A1
(43) Pub. Date: Apr. 27, 2017

(54) DISPLACEMENT LIQUID FOR SEMICONDUCTOR CIRCUIT PATTERN DRYING, AND THE METHOD

(71) Applicant: DUPONT-MITSUI FLUOROCHEMICALS CO., LTD., TOKYO (JP)

(72) Inventors: HIDEAKI KIKUCHI, Shizuoka (JP); TAKANORI MATSUMOTO, Shizuoka (JP); MIKI ITO, Shizuoka (JP)

(21) Appl. No.: 15/317,427

(22) PCT Filed: Jun. 11, 2015
(86) PCT No.: PCT/IB2015/001287

§ 371 Date: Dec. 9, 2016

(30) Foreign Application Priority Data
Jun. 11, 2014 (JP) 2014-120112

(51) Int. Cl. H01L 21/67; B08B 3/04; H01L 21/02

(52) U.S. Cl. CPC H01L 21/67034; H01L 21/02052; B08B 3/04

(57) ABSTRACT

An object of the present invention is to provide a replacement solution for drying a semiconductor pattern and a method for drying a semiconductor pattern, that can prevent breakdown of an intricate semiconductor pattern with a high aspect ratio, when drying after a washing process after edging is completed in a semiconductor manufacturing process. The present invention provides a replacement solution for drying a semiconductor pattern and method, containing a hydrofluoro ether and/or hydrofluorocarbon, that is completely miscible with isopropyl alcohol, has a boiling point of 70° C. or higher, and has surface tension under atmospheric conditions of 10 mN/m or lower when heated to a temperature below the boiling point.

### TECHNICAL FIELD

The present invention relates to a replacement solution for drying a semiconductor pattern, and a method for drying a semiconductor pattern, that can prevent breakdown of the semiconductor pattern.

### BACKGROUND TECHNOLOGY

In recent years, miniaturizing of semiconductor devices has advanced remarkably, and therefore there is demand to form intricate semiconductor patterns with a high aspect ratio.

Semiconductor patterns are formed on a semiconductor wafer by a lithography step and an etching step in a semiconductor manufacturing process, but with intricate semiconductor patterns that have a high aspect ratio, there is a possibility that the pattern will breakdown when drying after a washing process after the etching step is completed.

After the etching step, a chemical solution is provided to the surface of the wafer in order to remove the etching solution and the etching residue. The chemical solution is rinsed off (rinsed) using a water-based rinsing agent such as pure water or the like, and then drying is generally performed by replacement of the water-based rinsing agent which remains on the surface of the wafer with isopropyl alcohol (hereinafter also referred to as “IPA”) and the like, which has low surface tension and is miscible with the water-based rinsing agent. However, there is concern of causing a breakdown of the semiconductor pattern when using IPA or the like, due to the surface tension, similar to the case of directly drying the water, because of advances in miniaturizing the semiconductor pattern in recent years.

In order to prevent breakdown of the semiconductor pattern, a method of drying is known that performs replacement with a supercritical fluid that has zero surface tension, but this method has problems in that the equipment used is expensive and not suitable for mass production, and breakdown of the pattern cannot be prevented if moisture or the like is introduced into the chamber that achieves the supercritical environment (patent document 1).

On the other hand, a method is also known where a water repellent protective film is formed on the semiconductor wafer surface to prevent breakdown of the pattern during drying, but this method has a problem in that a portion of the surface processing agent that forms the water repellent protective film becomes residue and causes defects in the semiconductor pattern (patent document 2). (Ultrafine foreign material that causes this type of semiconductor element defect is generally referred to as particles.)

Furthermore, a method is also known that uses a solvent composition containing a solvent containing a fluorine compound and a fluorine-based surfactant as a replacement solution for a rinsing agent, but this method has problems in that the residual composition forms particles, and is not a sufficient resolution method (patent document 3).

### PRIOR TECHNOLOGY DOCUMENTS

### Patent Documents

Patent document 1: Japanese Unexamined Patent Application 2011-187570

Patent document 2: PCT Publication WO/2012/002346

Patent document 3: U.S. Pat. No. 4,442,324

### SUMMARY OF THE INVENTION

### Problem to be Resolved by the Invention

An object of the present invention is to provide a replacement solution for drying a semiconductor pattern and a method for drying a semiconductor pattern, that can prevent breakdown of an intricate semiconductor pattern with a high aspect ratio, during drying after a rinsing process.

### Means for Resolving Problems

As a result of diligent research, the present inventors discovered that the aforementioned object can be achieved by replacement of a water-based rinsing agent such as pure water or the like with isopropyl alcohol (IPA) when drying after rinsing a semiconductor wafer, and then performing replacement of the IPA with a specific hydrofluoroether (hereinafter also referred to as “HFE”) and/or hydrofluorocarbon (hereinafter also referred to as “HFC”), and thus the present invention was achieved.

In other words, the present invention includes the following points.

1. A replacement solution for drying a semiconductor pattern that performs replacement of isopropyl alcohol, containing hydrofluoro ether and/or hydrofluorocarbon, and that is completely miscible in isopropyl alcohol, has a boiling point of 70° C. or higher, and where the surface tension under atmospheric conditions is 10 mN/m or lower when heated to a temperature below the boiling point.
2. The replacement solution according to 1., wherein the boiling point is 83° C. or higher.
3. The replacement solution according to 1. or 2., wherein the hydrofluoro ether is methoxyperfluoro heptene.
4. The replacement solution according to 1. or 2., wherein the hydrofluorocarbon is tridecafluorooctane.
5. The replacement solution according to 4., wherein the tridecafluorooctane is 1,1,1,2,2,3,3,4,4,5,5,6,6,-tridecafluorooctane.
6. A method of drying a semiconductor pattern, including: rinsing after washing the semiconductor pattern, then performing replacement of the rinsing agent with isopropyl alcohol, then performing replacement with a replacement solution according to 1. through 5., and then heat drying.
7. The method of drying a semiconductor pattern according to 6., wherein drying is performed by heating to 70° C. or higher.

### Effect of the Invention

With the present invention, a semiconductor wafer can be dried without causing breakdown of an intricate semiconductor pattern when drying after rinsing the semiconductor wafer. Furthermore, the occurrence of particles after drying can be prevented.

### DESCRIPTION OF THE PREFERRED EMBODIMENTS

The present invention is described below in detail.

In the replacement solution of the present invention, the hydrofluoro ether (HFE) and/or the hydrofluorocarbon (HFC) that are used as the replacement solution are completely miscible in IPA. The IPA which is the solution for replacement can be efficiently removed because the replacement solution is completely miscible in IPA. In the present invention, completely miscible means that both liquids are miscible and there is no phase separation at any composition ratio.

In the replacement solution of the present invention, the HFE/HFC has a boiling point of 70° C. Herein, if the boiling point of the HFE/HFC is 83° C. or higher (above the boiling point of IPA), the HFE/HFC will not evaporate before the residual IPA, and thus a rise in the IPA concentration after HFE/HFC replacement can be prevented. Furthermore, as the boiling point of the replacement solution increases, drying can be performed at a higher temperature, and the surface tension of the replacement solution will be lower. Furthermore, at higher temperatures, the latent heat of the residual rinsing agent (primarily water) and the IPA will be lower, drying efficiency will be improved, and the drying time will be shortened. Therefore, the boiling point of the HFE/HFC is preferably 83° C. or higher, more preferably 100° C. or higher, even more preferably 105° C. or higher, and particularly preferably 110° C. or higher.

With the replacement solution of the present invention, the HFE/HFC can achieve a surface tension of 10 mN/m or less under atmospheric conditions. The surface tension can be measured by various types of methods such as the Wilhelmy method or the maximum bubble pressure method, or the like, or can be calculated from an equation. The surface tension is reduced as the temperature increases, and the following equation, known as the Brock-Bird) equation, is an equation that accurately expresses the temperature dependency. With the present invention, the surface tension of the HFE/HFC is calculated by the Brocl-Bird Bird equation.

σ=Pc^{2/3}TC^{1/3}Q(1=Tr)^{11/9}

Q=0.1207(1+Tbr·ln(Pc)/1−Tbr)−0.281 [Equation 1]

σ: surface tension (mN/m)
Pc: critical pressure (MPa)
Tc: critical temperature (K)
T: temperature (K)
Tr: Ratio of temperature to critical temperature, Tr=T/Tc
Tbr: Ratio of boiling point (Tb) to critical temperature, Tbr=Tb/Tc

In the replacement solution of the present invention, the HFE/HFC preferably can dissolve trace amount of moisture. Therefore, a trace amount of moisture that could not be completely removed by the IPA rinse as a result of making the pattern more intricate can be removed. The moisture solubility is preferably such that 50 ppm of moisture can be dissolved at 25° C.

With the replacement solution of the present invention, the HFE/HFC preferably has low global warming potential (GWP). Specifically, the GWP is 100 or less, more preferably 50 or less, and particularly preferably 10 or less. Furthermore, the ozone depletion coefficient is preferably zero.

With the replacement solution of the present invention, the HFE/HFC can be used individually, or two or more types can be used in combination.

The HFC that is used in the replacement solution of the present invention can be saturated or unsaturated, and is a compound that contains only 3 to 9 carbon atoms, preferably 4 to 8 carbon atoms, as well as fluorine and hydrogen atoms. Specific examples of the HFC include 1,1,1,2,2,3,3,4,4,5,5,6,6-tridecafluorooctane, 1,1,1,2,2,3,4,5,5,5-decafluoropentane, 1,1,1,3,3-pentafluorobutane, 1,1,2,2,3,3,4-heptafluoro cyclopentane, 1H-perfluoroheptane, 1,1,1,3,3-pentafluoropropane, hexafluorobutene, and the like, preferably tridecafluorooctane, and particularly preferable is a 1,1,1,2,2,3,3,4,4,5,5,6,6-tridecaflulorooctane with a boiling point of 114.7° C.

An example of HFC that is suitable for use is Asahiklin (registered trademark) AC-6000 produced by Asahi Glass Co., Ltd.

The HFE that is used in the replacement solution of the present invention can be saturated or unsaturated, and is a compound that has an ether bond and contains only 3 to 9 carbon atoms, preferably 4 to 8 carbon atoms, as well as hydrogen, fluorine, and oxygen atoms. Specific examples of the HFE include 1,1,1-trifluoroethyl-1,1,2,2-tetrafluoroethyl ether, nonafluorobutylmethyl ether, methoxyperfluoroheptene and the like, but methoxyperfluoroheptene with a boiling point of 110.5° C. and a GWP of <5 is preferable, but various isomers or mixtures thereof are also acceptable.

Examples of HFE that are suitably used include Vertrel (registered trademark) Suprion produced by Mitsui Dupont Fluorochemical Co., Ltd. and NoVec (registered trademark) 7200, Novec (registered trademark) 7500, and Novec (registered trademark) 7600, produced by Sumitomo 3M.

Furthermore, in the replacement solution of the present invention, the HFC/HFE is preferably used without mixing with another solvent such as IPA in order to prevent an increase in the surface tension and the moisture content, but a small amount of an organic solvent can be blended in order to adjust the drying temperature. Examples of the organic solvent to be blended include hydrocarbons, chlorinated hydrocarbons, alcohols, ketones, esters, and mixtures thereof. Examples of the hydrocarbons include pentane, hexane, heptane, and the like; examples of chlorinated hydrocarbons include dichloroethylene and the like, examples of alcohols include methanol, ethanol, propanol, and the like, examples of ketones include acetone, methyl isobutyl ketone and the like, and examples of esters include ethyl acetate, methyl acetate, butyl acetate, methoxy butyl acetate, Cellosolve acetate, amyl acetate, normal propyl acetate, isopropyl acetate, methyl lactate, ethyl lactate, butyl lactate, and the like. The organic solvent to be blended can be suitably set to a range that does not exceed 5 mass %.

With the replacement solution and the method for drying a semiconductor pattern according to the present invention, drying of the semiconductor pattern refers to drying by heating after supplying a chemical solution to the surface of the wafer after the etching step, and rinsing off the chemical solution, in a normal semiconductor manufacturing process. The rinsing process uses normal pure water as the rinsing agent, but an aqueous solution containing an additive such as a surfactant or the like can also be used. After rinsing, the rinsing agent such as pure water or the like is replaced by IPA, and then by the replacement solution made of HFC/HFE. The rinsing process, IPA replacement, and HFC/HFE replacement steps can all be performed by methods that are commonly known to one skilled in the art, but examples of these methods include a method of immersing the semiconductor wafer in the solution, or a method of dripping the solution like a shower, and the like.

Drying by heating after replacing with the replacement solution made of HFC/HFE according to the present invention can be performed by a method commonly known to one skilled in the art, but the heating temperature is preferably 70° C. or higher, more preferably 80° C. or higher, even more preferably 90° C. or higher, and particularly preferably 100° C. or higher.

### EXAMPLES

### Example 1

The temperature where the surface temperature calculated by the Brock-Bird equation was 10 mN/m was calculated for the compounds shown in Table 1 (all completely miscible with IPA) which are either a hydrofluoro ether or a hydrofluorocarbon (HFC). The results are shown in Table 2.

TABLE 1

| | | Boiling |
|---|---|---|
| | | Point |
| Product Name | Compound Name | (° C.) |
| Novec | 1-ethoxy-1,1,2,2,3,3,4,4,4- | 76 |
| (Registered | nonafluorobutane | |
| Trademark) | | |
| 7200 | | |
| Manufactured | | |
| by Sumitomo | | |
| 3M Ltd. | | |
| Novec | 3-ethoxy-1,1,1,2,3,4,4,5,5,6,6,6- | 130 |
| (Registered | dodecafluoro-2- | |
| Trademark) | (trifluoromethyl)-hexane | |
| 7500 | | |
| Manufactured | | |
| by Sumitomo | | |
| 3M Ltd. | | |
| Novec | 1,1,1,2,3,3-hexafluoro-4-(1,1,2,3,3,3- | 131 |
| (Registered | hexa fluoropropoxy)-pentane | |
| Trademark) | | |
| 7600 | | |
| Manufactured | | |
| by Sumitomo | | |
| 3M Ltd. | | |
| Asahiklin | 1,1,1,2,2,3,3,4,4,5,5,6,6,-tridecafluoro- | 114.7 |
| (Registered | octane | |
| Trademark) | | |
| AC-6000 | | |
| Manufactured | | |
| by Asahi Glass | | |
| Co. | | |
| Vertrel | methoxyperfluoroheptane isomer mixture | 110.5 |
| (Registered | | |
| Trademark) | | |
| Suprion | | |
| Manufactured | | |
| by Du Pont- | | |
| Mitsui | | |
| Fluorochemicals | | |
| Co., Ltd. | | |

TABLE 2

| | Product Name | | | | | |
|---|---|---|---|---|---|---|
| | Novec ® | Novec ® | Novec ® | Asahiklin ® | | |
| | 7200 | 7500 | 7600 | AC-6000 | Vertrel ® Suprion | IPA |
| Boiling Point | 76 | 130 | 131 | 114.7 | 110.5 | 83 |
| 60 | 10.7 | 12.6 | 14.2 | 13.6 | 12.3 | 26 |
| 70 | 9.9 | 11.8 | 13.4 | 12.7 | 11.5 | 24.2 |
| 80 | | 11.1 | 12.5 | 11.8 | 10.6 | 22.4 |
| 90 | | 10.3 | 11.7 | 10.9 | 9.8 | |
| 100 | | 9.6 | 10.8 | 10.1 | 9 | |
| 110 | | 8.9 | 10 | 9.2 | 8.3 | |
| 120 | | 8.2 | 9.2 | | | |
| 130 | | | 8.4 | | | |

### Possibility of Industrial Application

The replacement solution of the present invention containing hydrofluoro ether (HFE) and/or hydrofluorocarbon (HFC) is used by replacing isopropyl alcohol (I PA) that has replaced a water-based rinsing agent such as pure water or the like when drying after a rinsing process of a semiconductor wafer, and therefore the surface tension can be greatly reduced at the drying temperature as compared to IPA, and therefore breakdown of an intricate semiconductor pattern with a high aspect ratio can be prevented, and thus the present invention can be suitably used in a semiconductor manufacturing process.

what is claimed is:

1. A replacement solution for drying a semiconductor pattern that performs replacement of isopropyl alcohol, containing hydrofluoro ether and/or hydrofluorocarbon, and that is completely miscible in isopropyl alcohol, has a boiling point of 70° C. or higher, and where the surface tension under atmospheric conditions is 10 mN/m or lower when heated to a temperature below the boiling point.

2. The replacement solution according to claim 1, wherein the boiling point is 83° C. or higher.

3. The replacement solution according to claim 1 or 2, wherein the hydrofluoro ether is methoxyperfluoro heptene.

4. The replacement solution according to claim 1 or 2, wherein the hydrofluorocarbon is tridecafluorooctane.

5. The replacement solution according to claim 4, wherein the tridecafluorooctane is 1,1,1,2,2,3,3,4,4,5,5,6,6,-tridecafluorooctane.

6. A method of drying a semiconductor pattern, comprising: rinsing after washing the semiconductor pattern, then performing replacement of the rinsing agent with isopropyl alcohol, then performing replacement with a replacement solution according to claim 1 through claim 5, and then heat drying.

7. The method of drying a semiconductor pattern according to claim 6, wherein drying is performed by heating to 70° C. or higher.
